(19) United States
(12) Patent Application Publication
(10) Pub. No.: US 2022/0005766 A1
(43) Pub. Date: Jan. 6, 2022

(54) COMPOSITE HEAT INSULATION STRUCTURE FOR MONOCRYSTALLINE SILICON GROWTH FURNACE AND MONOCRYSTALLINE SILICON GROWTH FURNACE

(71) Applicants: Shanghai Institute of Microsystem and Information Technology, Chinese Academy of Sciences, Shanghai (CN); Zing Semiconductor Corporation, Shanghai (CN)

(72) Inventors: Xing Wei, Shanghai (CN); Minghao Li, Shanghai (CN); Zhan Li, Shanghai (CN); Tao Wei, Shanghai (CN); Yun Liu, Shanghai (CN); Zhongying Xue, Shanghai (CN)

(21) Appl. No.: 17/138,842

(22) Filed: Dec. 30, 2020

(30) Foreign Application Priority Data
Jul. 1, 2020 (CN) 202010621637.8

(51) Int. Cl. H01L 23/538; H01L 23/532

(52) U.S. Cl. CPC H01L 23/5385; H01L 23/5329

(57) ABSTRACT

Disclosed is a composite heat insulation structure for a monocrystalline silicon growth furnace, comprising a supporting layer and a laminated structure on the supporting layer. The laminated structure comprises one or more first refractive layers and one or more second refractive layers which have different refractivity and are disposed alternately. Also disclosed is a monocrystalline silicon growth furnace in which the composite heat insulation structure is disposed on a heat shield. When disposed on a heat shield to be applied to the monocrystalline silicon growth furnace, the composite heat insulation structure can improve ability of the heat shield to reflect heat energy, reduce heat dissipation of silicon melt, and play a role of heat insulation on a heat field, thereby improving the quality of the heat field to improve the quality and yield of monocrystalline silicon.

### CROSS REFERENCE TO RELATED APPLICATIONS

The present application claims the benefit of Chinese Patent Application No. 202010621637.8 filed on Jul. 1, 2020, the contents of which are incorporated herein by reference in their entirety.

### TECHNICAL FIELD

The present invention relates to the field of manufacturing of semiconductors, and in particular to a composite heat insulation structure for a monocrystalline silicon growth furnace and a monocrystalline silicon growth furnace.

### BACKGROUND

Monocrystalline silicon plays an irreplaceable role as a material basis for sustainable development of industries of modern communication technology, integrated circuits, solar cells, and so on. At present, main methods for growing monocrystalline silicon from melt include the Czochralski method and the zone melting method. The Czochralski method for growing monocrystalline silicon has advantages of simple equipment and processes, easy to achieve automatic control, high production efficiency, easy preparation of a large-diameter monocrystalline silicon, as well as fast crystal growth, high crystal purity and high integrity, so that the Czochralski method has been rapidly developed.

To produce monocrystalline silicon in a monocrystalline silicon growth furnace using the Czochralski method, common silicon materials need to be melted and then recrystallized. According to the crystallization law of monocrystalline silicon, a raw material is heated and melted in a crucible, with a temperature controlled to be slightly higher than a crystallization temperature of silicon single crystal, to ensure that the molten raw material can be crystallized on the surface of the solution. The crystallized single crystal is pulled out of the liquid level through a pulling system of the Czochralski furnace, cooled and shaped under the protection of an inert gas, and finally crystallized into a crystal with a cylindrical body and a cone tail.

Monocrystalline silicon is grown in the heat field of the single crystal furnace, and thus the quality of the heat field significantly influences the growth and quality of the monocrystalline silicon. A good heat field can not only allow a single crystal to grow successfully, but also produce a high-quality single crystal. When heat field conditions are not sufficient, a single crystal may not be grown, and even though a single crystal is grown, the single crystal may be transformed to a polycrystal or has a structure with a large number of defects due to crystal transformation. Therefore, it is a very critical technology in a Czochralski monocrystalline silicon growth process to find better conditions and best configuration of the heat field. In the design of a heat field, the most critical is the design of a heat shield. Firstly, the design of the heat shield directly influences the vertical temperature gradient of the solid-liquid interface, and determines the crystal quality by influencing a V/G ratio with changed temperatures. Secondly, the design of the heat shield will influence the horizontal temperature gradient of the solid-liquid interface, and control the quality uniformity of the entire silicon wafer. Finally, a properly designed heat shield will influence the heat history of the crystal, and control nucleation and growth of defects inside the crystal. Therefore, the design of the heat shield is very critical in the process of preparing high-grade silicon wafers.

At present, an outer layer of a commonly used heat shield is a SiC coating layer or pyrolytic graphite, and an inner layer the commonly used heat shield heat-insulating graphite felt. The heat shield which is cylindric is positioned in an upper portion of the heat field. A crystal bar is pulled out of the cylindric heat shield. The graphite of the heat shield which is close to the crystal bar has a lower heat reflectivity and absorbs heat emitted from the crystal bar. The graphite on the outside surface of the heat shield usually has a higher heat reflectivity, which is beneficial to reflect back the heat emitted from the melt, thereby improving the heat insulation performance for the heat field and reducing power consumption of the whole process. However, the existing heat shields still have the defect of non-uniform temperature gradient.

In view of the above-mentioned defects in the prior art, the present invention is intended to provide a composite heat insulation structure which can be applied to a heat shield to improve the heat reflectivity of the heat shield, thereby increasing quality and yield of the crystal grown in the furnace.

### SUMMARY

In view of the abovementioned problems in the prior art, an objective of the present invention is to provide a composite heat insulation structure for a monocrystalline silicon growth furnace, a supporting layer and a laminated structure prepared on the supporting layer; the laminated structure comprises one or more first refractive layers and one or more second refractive layers which have different refractivity from that of the one or more first refractive layers, and the one or more first refractive layers and the one or more second refractive layers are disposed alternately.

In a preferred embodiment, the laminated structure is connected to the supporting layer via the first refractive layer, or the laminated structure is connected to the supporting layer via the second refractive layer.

In a preferred embodiment, all the first refractive layers are made of silicon, and each of the first refractive layers has a thickness in a range from 0.1 μm to 1 μm and roughness of less than 1.5 A.

In a preferred embodiment, all the second refractive layers are made of silicon dioxide, and each of the second refractive layers has a thickness in a range from 0.1 μm to 1 μm and roughness of less than 2 A.

In a preferred embodiment, all the second refractive layers are made of silicon nitride, and each of the second refractive layers has a thickness in a range from 0.1 μm to 1 μm and roughness of less than 2 A.

In a preferred embodiment, at least one of the second refractive layers in the laminated structure is made of silicon oxide, and at least one of the second refractive layers in the laminated structure is made of silicon nitride.

In a preferred embodiment, the supporting layer is made of silicon, silicon dioxide or molybdenum, and the supporting layer has a thickness in a range from 1 mm to 3 mm.

In a preferred embodiment, the first refractive layer and the second refractive layer are prepared by physical vapor deposition, chemical vapor deposition, or a chemical mechanical polishing process.

In a preferred embodiment, the composite heat insulation structure is further provided with an encapsulation layer for encapsulating the supporting layer and the laminated structure.

In another aspect, a monocrystalline silicon growth furnace is provided in the present invention, which comprises a furnace body, a crucible, a heater unit, a heat shield, and a composite heat insulation structure as described in the above technical solutions; wherein, the composite heat insulation structure is disposed on the heat shield;

a cavity is disposed in the furnace body;

the crucible is disposed in the cavity and is used for containing melt for growth of monocrystalline silicon;

the heater unit is disposed between the crucible and the furnace body and is used to provide a heat field required for the growth of the monocrystalline silicon; and

the heat shield is disposed in an upper portion of the crucible and is used to reflect heat energy emitted from the melt of the crucible, and the composite heat insulation structure is disposed on a side of the heat shield close to the crucible and/or the composite heat insulation structure is disposed on a side of the crucible close to the monocrystalline silicon grown.

By adopting the aforementioned technical solutions, the present invention has the following beneficial effects:

The composite heat insulation structure for a monocrystalline silicon growth furnace provided in the present invention has good heat reflectivity in the wavelength range of heat radiation. When disposed on a heat shield to be applied to the monocrystalline silicon growth furnace, the composite heat insulation structure can improve ability of the heat shield to reflect heat energy, reduce heat dissipation of silicon melt, and play a role of heat insulation on a heat field, thereby improving the quality of the heat field to improve the quality and yield of monocrystalline silicon.

### BRIEF DESCRIPTION OF DRAWINGS

In order to more clearly illustrate the technical solutions of the present invention, the drawings that are used in the description of the embodiments or the prior art will be briefly introduced hereafter. Obviously, the drawings in the following description are only some embodiments of the present invention, and other drawings can be obtained based on these drawings by those of ordinary skill in the art without creative work.

FIGS. 1A to 1E are schematic structural diagrams of composite heat insulation structures for a monocrystalline silicon growth furnace according to an embodiment of the present invention;

FIG. 2 is a graph showing heat reflectivity of the respective composite heat insulation structure of FIGS. 1A to 1E;

FIGS. 3A to 3B are schematic structural diagrams of composite heat insulation structures for a monocrystalline silicon growth furnace according to another embodiment of the present invention;

FIG. 4 is a graph showing heat reflectivity of the respective composite heat insulation structure of FIGS. 3A to 3B;

FIG. 5A to 5B are schematic structural diagrams of composite heat insulation structures for a monocrystalline silicon growth furnace according to a further embodiment of the present invention; and

FIG. 6 is a graph showing the heat reflectivity of the respective composite heat insulation structures of FIGS. 5A to 5B.

In the drawings: supporting layer, 20—laminated structure, 21—first refractive layer, 22—second refractive layer, 22(I)—second refractive layer made of silicon dioxide, and 22(II)—second refractive layer made of silicon nitride.

### DETAILED DESCRIPTION

Hereafter, the technical solutions according to embodiments of the present invention will be described clearly and thoroughly with reference to drawings. Obviously, the described embodiments are only part of, not all of, the embodiments of the present invention. Based on the embodiments of the present invention, all other embodiments obtained by those of ordinary skill in the art without any creative work shall fall within the protection scope of the present invention.

It should be noted that the terms “first”, “second”, or the like as used in the specification and claims of the present invention and in the above-mentioned drawings are used to distinguish similar objects, and are not intended to define a particular order or a sequential order. It should be understood that data used with reference to the terms may be interchanged, where appropriate, so that the embodiments of the present invention described herein can be implemented in an order other than those illustrated or described herein. In addition, the terms “comprising”, “including”, “having”, and any variations thereof, are intended to encompass non-exclusive inclusions.

### Embodiment 1

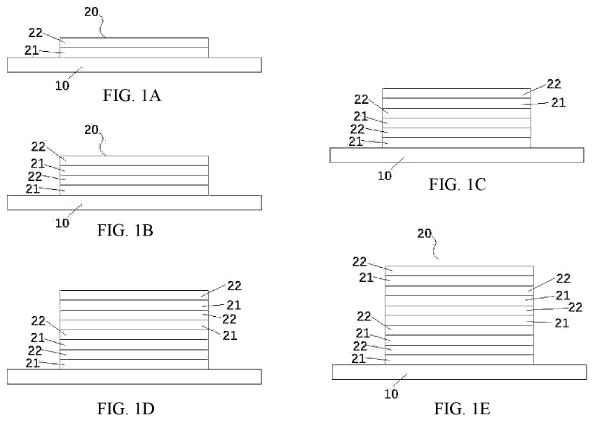

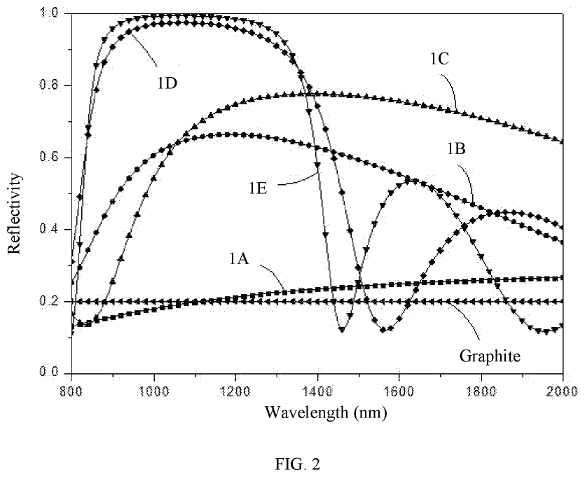

Refer to FIGS. 1A to 1E and FIG. 2. A composite heat insulation structure for a monocrystalline silicon growth furnace according to the embodiment of the present invention comprises a supporting layer 10 and a laminated structure 20 prepared on the supporting layer 10. The laminated structure 20 comprises one or more first refractive layers 21 and one or more second refractive layers 22 which have different refractivity from that of the one or more first refractive layers 21. The one or more first refractive layers 21 and the one or more second refractive layers 22 are disposed alternately.

It should be noted that in the embodiment, the first refractive layer 21 and the second refractive layer 22 exist in pairs. That is, the number of the first refractive layers 21 equals to that of the second refractive layers 22, such that one side of the laminated structure is ended with the first refractive layer 21, and the other side of the laminated structure is ended with the second refractive layer 22. The laminated structure 20 is connected to the supporting layer 10 via the first refractive layer 21 or the second refractive layer 22.

All the first refractive layers 21 are made of silicon, and each of the first refractive layers 21 has a thickness in a range from 0.1 μm to 1 μm and roughness of less than 1.5 A.

All the second refractive layers 22 are made of silicon dioxide, and each of the second refractive layers 22 has a thickness in a range from 0.1 μm to 1 μm and roughness of less than 2 A.

The supporting layer 10 is made of silicon, silicon dioxide or molybdenum, and has a thickness in a range from 1 mm to 3 mm.

The one or more first refractive layers 21 and the one or more second refractive layers 23 are prepared layer by layer on the supporting layer 10 by physical vapor deposition, chemical vapor deposition, or a chemical mechanical polishing process.

The composite heat insulation structure is further provided with an encapsulation layer for encapsulating the supporting layer 10 and the laminated structure 20 as a whole.

It should be noted that in these structures of FIGS. 1B to 1E, when the laminated structures 20 have two or more of the first refractive layers 21, the first refractive layers 21 may each have the same thickness or different thicknesses, as long as each of the first refractive layers 21 has a thickness in a range from 0.1 μm to 1 μm. Likewise, when the laminated structure 20 has two or more of the second refractive layers 22, the second refractive layers 20 may each have the same thickness or different thicknesses, as long as each of the second refractive layers 22 has a thickness in a range from 0.1 μm to 1 μm.

As shown in FIGS. 1A to 1E, the composite heat insulation structures with different numbers of the first refractive layer-second refractive layer pairs are provided in the embodiment. In each of the composite heat insulation structures, each of the first refractive layers 21 is made of silicon with a thickness of 0.1 μm, and each of the second refractive layers 22 is made of silicon dioxide with a thickness of 0.1 μm. Here, the second refractive layer made of silicon dioxide is denoted as 22(I). The laminated structures 20 are each connected to the supporting layer 10 via the first refractive layers 21. That is, a first first refractive layer 21 is firstly prepared on the supporting layer 10, then a first second refractive layer 22 is prepared thereon, and subsequent layers are prepared alternately. The supporting layer 10 is made of silicon, and has a thickness of 1 mm. The heat reflectivity of the respective composite heat insulation structures are shown in FIG. 2.

As can be seen from FIG. 2, the composite heat insulation structure of FIG. 1A has the lowest thermal reflectivity. This is because the composite heat insulation structure has only one interface. Thus, the number of the first refractive layer-second refractive layer pairs is preferably larger than 1.

As the number of the first refractive layer-second refractive layer pairs increases, the number of the interfaces also increases, and the heat reflectivity in a wavelength range from 800 nm to 1400 nm also increases. When the number of the first refractive layer-second refractive layer pairs increases to four or more, although the heat reflectivity in the wavelength range from 800 nm to 1400 nm still tends to increase, the heat reflectivity in a wavelength range from 1400 nm to 2000 nm decreases significantly. As a whole, the rate of increase for the heat reflectivity is not significantly improved, or even is reduced. However, the composite heat insulation structures according to the embodiment have excellent heat reflecting performance as compared to heat insulation structures made of graphite material in prior art. In summary, the number of the first refractive layer-second refractive layer pairs is suitably in a range from 2 to 5.

A monocrystalline silicon growth furnace is also provided according the embodiment, which comprises a furnace body, a crucible, a heater unit, a heat shield, and a composite heat insulation structure provided in the above-mentioned technical solutions, wherein the composite heat insulation structure is disposed on the heat shield.

A cavity is provided in the furnace body. The crucible is disposed in the cavity and located in the center of the cavity. The crucible is recessed in the central portion and is used for containing melt for growth of monocrystalline silicon. The crucible may be prepared from quartz (silicon dioxide), or may be prepared from graphite. Alternatively, the crucible may comprise an inner wall made of quartz material and an outer wall made of graphite material, such that the inner wall of the crucible can directly contact silicon melt, and the outer wall of the crucible made of graphite can play a supporting role.

The heater unit is positioned around the crucible and between the crucible and the furnace body, thereby providing a heat field required for the growth of the monocrystalline silicon. There is a space between the heater unit and the crucible. The space may be adjusted depending on parameters such as the size of the cavity, the size of the crucible, the heating temperature, and so on. The heater unit is preferably a graphite heater unit. Further, the heater unit may comprise one or more heaters disposed around the crucible to make the heat field in which the crucible is located uniform.

The heat shield is disposed in an upper portion of the crucible, and is used to reflect heat energy emitted from the melt contained in the crucible, thereby playing a heat preservation role.

The composite heat insulation structure is disposed on a side of the heat shield close to the crucible, and/or the composite heat insulation structure is disposed on a side of the crucible close to the monocrystalline silicon grown.

Furthermore, the monocrystalline silicon growth furnace may also comprise a cooler for cooling a monocrystalline silicon ingot grown. The crucible may also connected with an elevator mechanism and a rotation mechanism. The elevator mechanism is used to raise and lower the crucible. The rotation mechanism is used to rotate the crucible. The crucible can be raised/lowered and rotated in the heat field provided by the heater unit, which is beneficial to provide a good heat field environment. Thus, the silicon melt inside the crucible can also be positioned in a uniform heat environment.

When the composite heat insulation structure according to the embodiment is disposed on a heat shield to be applied to the monocrystalline silicon growth furnace, it can improve ability of the heat shield to reflect heat energy, reduce heat dissipation of silicon melt, and play a role of heat insulation on a heat field, thereby improving the quality of the heat field to improve the quality and yield of monocrystalline silicon.

### Embodiment 2

In Embodiment 1, the first refractive layer 21 and the second refractive layer 22 exist in pairs. When the number of the first refractive layer-second refractive layer pairs is two or three, the composite heat insulation structure formed therefrom has a relatively good heat reflection property.

The composite heat insulation structures provided according to the embodiment differ from that of Embodiment 1 in that: the number of the first refractive layers 21 is not equal to that of the second refractive layers 22.

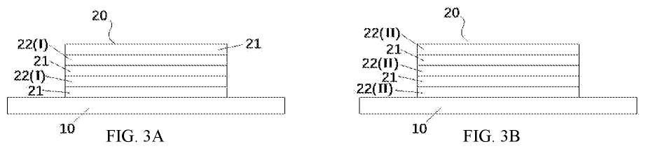

Refer to FIG. 3A. The composite heat insulation structure provided in the embodiment comprises three first refractive layers 21 and two second refractive layers 22. The first refractive layers 21 have different refractivity from that of the second refractive layers 22. The first refractive layers 21 and the second refractive layers 22 are disposed alternately, such that each end of the laminated structure is the first refractive layer 21. The supporting layer 10 is connected to the laminated structure 20 via the first reflective layer 21.

All the first refractive layers 21 in the laminated structure 20 are made of silicon, and each of the first refractive layers 21 has a thickness of 0.3 μm and roughness of less than 1 A.

The two second refractive layers 22 in the laminated structure 20 are made of silicon dioxide, which are denoted as 22(I), and each of the second refractive layers 22(I) has a thickness of 0.3 μm and roughness of less than 1 A.

The supporting layer 10 is made of silicon, and has a thickness of 3 mm.

Refer to FIG. 3B. The composite heat insulation structure provided in the embodiment comprises three second refractive layers 22 and two first refractive layers 21. The first refractive layers 21 have different refractivity from that of the second refractive layers 22. The first refractive layers 21 and the second refractive layers 22 are disposed alternately, such that each end of the laminated structure is the second refractive layer 22. The supporting layer 10 is connected to the laminated structure 20 via the second reflective layer 22.

The first refractive layers 21 in the laminated structure 20 are each made of silicon, and each of the first refractive layers 21 has a thickness of 1 μm and roughness of less than 1 A.

The second refractive layer 22 in the laminated structure 20 are each made of silicon nitride. Here, the second refractive layer made of silicon nitride is denoted as 22(II). The second refractive layer 22(II) has a thickness of 0.1 μm and roughness of less than 2 A.

The supporting layer 10 is made of silicon dioxide, and has a thickness in a range from 1 mm to 3 mm.

It should be noted that in the embodiment, the numbers of the first refractive layers 21 and the second refractive layers 22 are merely illustrative, and can be other values that are different from that provided in the embodiment.

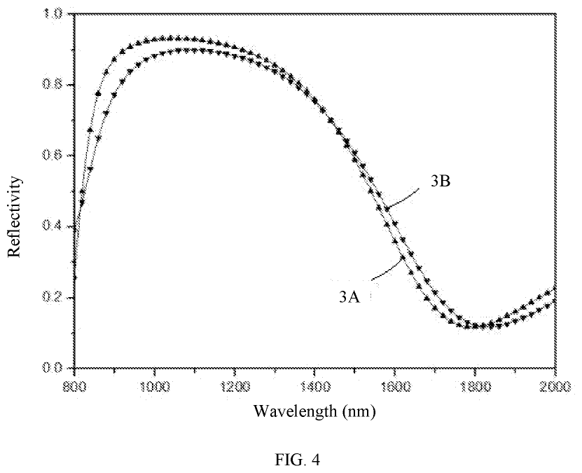

FIG. 4 is a graph showing heat reflectivity of the two composite heat insulation structures of FIGS. 3A to 3B. As can be seen from FIG. 4, the heat reflectivity for the two composite heat insulation structures are similar with that of the composite heat insulation structure of FIG. 1D in Embodiment 1, and the heat reflection properties for the composite heat insulation structures of FIGS. 3A to 3B are slightly better than that of the composite heat insulation structure of FIG. 1D. This is because the numbers of the interfaces in the two composite heat insulation structures of FIGS. 3A to 3B are comparable to that in the composite heat insulation structure of FIG. 1D, such that when the respective layers in the laminated structures have a thickness in a suitable range, the laminated structures all have better heat reflection properties as compared to that in the prior art.

### Embodiment 3

The composite heat insulation structure for a monocrystalline silicon growth furnace according to the embodiment comprises a supporting layer 10 and a laminated structure 20 prepared on the supporting layer 10. The laminated structure 20 comprises first refractive layers 21 and second refractive layers 22 which have different refractivity from that of the first refractive layers 21. The first refractive layers 21 and the second refractive layers 22 are disposed alternately. The composite heat insulation structures for a monocrystalline silicon growth furnace according to the embodiment differ from that in Embodiment 1 in that there are at least two second refractive layers 22, and at least one of the second refractive layers 22 in the laminated structure 20 is made of silicon dioxide. The at least one of the second refractive layers 22 made of silicon dioxide has a thickness of 1 μm and roughness of less than 1 A. Alternatively, at least one of the second refractive layers 22 in the laminated structure 20 is made of silicon nitride, and the at least one of the second refractive layers 22 made of silicon nitride has a thickness of 1 μm and roughness of less than 1 A.

The first refractive layer 21 in the laminated structure 20 is made of silicon, and has a thickness of 0.5 μm and roughness of less than 1.2 A.

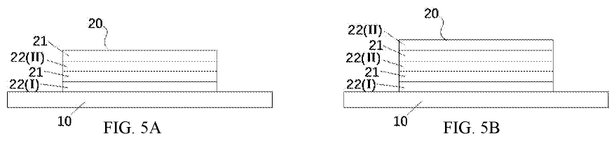

As an example, as shown in FIG. 5A, in the composite heat insulation structure for a monocrystalline silicon growth furnace provided in the embodiment, the supporting layer 10 is made of molybdenum and has a thickness of 1 mm. A first second refractive layer 22(I) made of silicon dioxide is firstly grown on the supporting layer 10, then a first first refractive layer 21 made of silicon is grown thereon, then a second second refractive layer 22(II) made of silicon nitride is grown thereon, and finally a second first refractive layer 21 made of silicon is grown thereon.

The composite heat insulation structure as shown in FIG. 5B differs from that as shown in FIG. 5A in that the supporting layer 10 is made of molybdenum with a thickness of 3 mm, and a third second refractive layer 22(II) made of silicon nitride is provided on a side of the laminated structure 20 away from the supporting layer 10 and has a thickness of 0.3 μm.

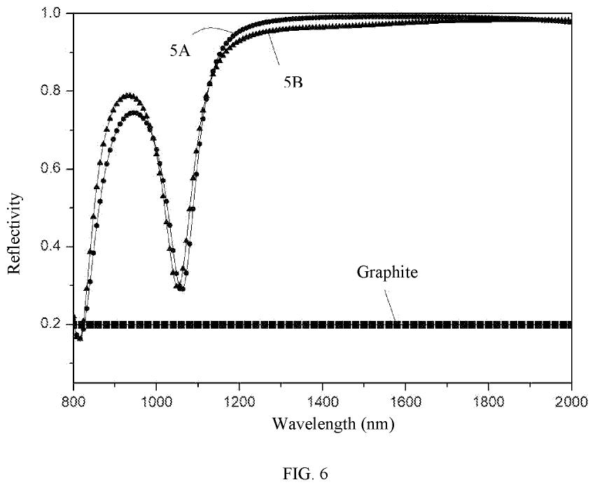

FIG. 6 is a graph showing heat reflectivity of the composite heat insulation structures for a monocrystalline silicon growth furnace of FIGS. 5A to 5B. As shown in FIG. 6, the composite heat insulation structure obtained based on the supporting layer made of molybdenum has an excellent heat reflection property in a wavelength range from 1200 nm to 2000 nm.

As known from the above embodiments, the number of the interfaces formed by alternately disposing the first refractive layers and the second refractive layers is suitably in a range from 2 to 9. Blindly increasing the number of the interfaces cannot achieve a monotonic increase in the heat reflectivity, but instead causes not only defects in the heat reflectivity in certain wavelength ranges, but also an increase in manufacturing costs.

It should be noted that differences among the embodiments are described in the description of the present invention. In addition to the above embodiments, more thin-film heat insulation sheets other than those provided in the above embodiments can be obtained based on the features disclosed above by combining various layers in the thin-film heat insulation sheet.

The above-mentioned embodiments are preferred embodiments of the present invention, and are not intended to limit the present invention. It is apparent that to those skilled in the art that the present invention is not limited to the exemplary embodiments and can be implemented in other specific forms without departing from the spirit or essential features of the present invention. Therefore, from any point of view, the embodiments should be regarded as exemplary and non-limiting. All equivalent changes and modifications made in accordance with the present invention fall within the scope of the present invention defined by the attached claims. Any reference signs in the claims should not be regarded as limiting the claims involved.

1. A composite heat insulation structure for a monocrystalline silicon growth furnace, wherein the composite heat insulation structure for a monocrystalline silicon growth furnace comprises a supporting layer (10) and a laminated structure (20) prepared on the supporting layer (10); the laminated structure (20) comprises one or more first refractive layers (21) and one or more second refractive layers (22) which have different refractivity from that of the one or more first refractive layers (21), and the one or more first refractive layers (21) and the one or more second refractive layers (22) are disposed alternately.

2. The composite heat insulation structure for a monocrystalline silicon growth furnace of claim 1, wherein the laminated structure (20) is connected to the supporting layer (10) via the first refractive layer (21), or the laminated structure (20) is connected to the supporting layer (10) via the second refractive layer (22).

3. The composite heat insulation structure for a monocrystalline silicon growth furnace of claim 2, wherein all the first refractive layers (21) are made of silicon, and each of the first refractive layers (21) has a thickness in a range from 0.1 μm to 1 μm and roughness of less than 1.5 A.

4. The composite heat insulation structure for a monocrystalline silicon growth furnace of claim 3, wherein all the second refractive layers (22) are made of silicon dioxide, and each of the second refractive layers (22) has a thickness in a range from 0.1 μm to 1 μm and roughness of less than 2 A.

5. The composite heat insulation structure for a monocrystalline silicon growth furnace of claim 3, wherein all the second refractive layers (22) are made of silicon nitride, and each of the second refractive layers (22) has a thickness in a range from 0.1 μm to 1 μm and roughness of less than 2 A.

6. The composite heat insulation structure for a monocrystalline silicon growth furnace of claim 3, wherein at least one of the second refractive layers (22) in the laminated structure (20) is made of silicon oxide, and at least one of the second refractive layers (22) in the laminated structure (20) is made of silicon nitride.

7. The composite heat insulation structure for a monocrystalline silicon growth furnace of claim 4, wherein the supporting layer (10) is made of silicon, silicon dioxide or molybdenum, and the supporting layer (10) has a thickness in a range from 1 mm to 3 mm.

8. The composite heat insulation structure for a monocrystalline silicon growth furnace of claim 5, wherein the supporting layer (10) is made of silicon, silicon dioxide or molybdenum, and the supporting layer (10) has a thickness in a range from 1 mm to 3 mm.

9. The composite heat insulation structure for a monocrystalline silicon growth furnace of claim 6, wherein the supporting layer (10) is made of silicon, silicon dioxide or molybdenum, and the supporting layer (10) has a thickness in a range from 1 mm to 3 mm.

10. The composite heat insulation structure for a monocrystalline silicon growth furnace of claim 7, wherein the first refractive layer (21) and the second refractive layer (23) are prepared by physical vapor deposition, chemical vapor deposition, or a chemical mechanical polishing process.

11. The composite heat insulation structure for a monocrystalline silicon growth furnace of claim 8, wherein the first refractive layer (21) and the second refractive layer (23) are prepared by physical vapor deposition, chemical vapor deposition, or a chemical mechanical polishing process.

12. The composite heat insulation structure for a monocrystalline silicon growth furnace of claim 9, wherein the first refractive layer (21) and the second refractive layer (23) are prepared by physical vapor deposition, chemical vapor deposition, or a chemical mechanical polishing process.

13. The composite heat insulation structure for a monocrystalline silicon growth furnace of claim 1, wherein the composite heat insulation structure is further provided with an encapsulation layer for encapsulating the supporting layer (10) and the laminated structure (20).

14. A monocrystalline silicon growth furnace, wherein the monocrystalline silicon growth furnace comprises a furnace body, a crucible, a heater unit, a heat shield, and a composite heat insulation structure of claim 1; the composite heat insulation structure is disposed on the heat shield;
a cavity is provided in the furnace body;
the crucible is disposed in the cavity and used for containing melt for growth of monocrystalline silicon;
the heater unit is disposed between the crucible and the furnace body to provide a heat field required for the growth of the monocrystalline silicon; and
the heat shield is disposed in an upper position of the crucible to reflect heat energy emitted from the melt in the crucible, and the composite heat insulation structure is disposed on a side of the heat shield close to the crucible and/or the composite heat insulation structure is disposed on a side of the crucible close to the monocrystalline silicon grown.

15. A monocrystalline silicon growth furnace, wherein the monocrystalline silicon growth furnace comprises a furnace body, a crucible, a heater unit, a heat shield, and a composite heat insulation structure of claim 2; the composite heat insulation structure is disposed on the heat shield;
a cavity is provided in the furnace body;
the crucible is disposed in the cavity and used for containing melt for growth of monocrystalline silicon;
the heater unit is disposed between the crucible and the furnace body to provide a heat field required for the growth of the monocrystalline silicon; and
the heat shield is disposed in an upper position of the crucible to reflect heat energy emitted from the melt in the crucible, and the composite heat insulation structure is disposed on a side of the heat shield close to the crucible and/or the composite heat insulation structure is disposed on a side of the crucible close to the monocrystalline silicon grown.

16. A monocrystalline silicon growth furnace, wherein the monocrystalline silicon growth furnace comprises a furnace body, a crucible, a heater unit, a heat shield, and a composite heat insulation structure of claim 3; the composite heat insulation structure is disposed on the heat shield;
a cavity is provided in the furnace body;
the crucible is disposed in the cavity and used for containing melt for growth of monocrystalline silicon;
the heater unit is disposed between the crucible and the furnace body to provide a heat field required for the growth of the monocrystalline silicon; and
the heat shield is disposed in an upper position of the crucible to reflect heat energy emitted from the melt in the crucible, and the composite heat insulation structure is disposed on a side of the heat shield close to the crucible and/or the composite heat insulation structure is disposed on a side of the crucible close to the monocrystalline silicon grown.

17. A monocrystalline silicon growth furnace, wherein the monocrystalline silicon growth furnace comprises a furnace body, a crucible, a heater unit, a heat shield, and a composite heat insulation structure of claim 4; the composite heat insulation structure is disposed on the heat shield;
a cavity is provided in the furnace body;
the crucible is disposed in the cavity and used for containing melt for growth of monocrystalline silicon;
the heater unit is disposed between the crucible and the furnace body to provide a heat field required for the growth of the monocrystalline silicon; and
the heat shield is disposed in an upper position of the crucible to reflect heat energy emitted from the melt in the crucible, and the composite heat insulation structure is disposed on a side of the heat shield close to the crucible and/or the composite heat insulation structure is disposed on a side of the crucible close to the monocrystalline silicon grown.

18. A monocrystalline silicon growth furnace, wherein the monocrystalline silicon growth furnace comprises a furnace body, a crucible, a heater unit, a heat shield, and a composite heat insulation structure of claim 5; the composite heat insulation structure is disposed on the heat shield;
a cavity is provided in the furnace body;
the crucible is disposed in the cavity and used for containing melt for growth of monocrystalline silicon;
the heater unit is disposed between the crucible and the furnace body to provide a heat field required for the growth of the monocrystalline silicon; and
the heat shield is disposed in an upper position of the crucible to reflect heat energy emitted from the melt in the crucible, and the composite heat insulation structure is disposed on a side of the heat shield close to the crucible and/or the composite heat insulation structure is disposed on a side of the crucible close to the monocrystalline silicon grown.

19. A monocrystalline silicon growth furnace, wherein the monocrystalline silicon growth furnace comprises a furnace body, a crucible, a heater unit, a heat shield, and a composite heat insulation structure of claim 6; the composite heat insulation structure is disposed on the heat shield;
a cavity is provided in the furnace body;
the crucible is disposed in the cavity and used for containing melt for growth of monocrystalline silicon;
the heater unit is disposed between the crucible and the furnace body to provide a heat field required for the growth of the monocrystalline silicon; and
the heat shield is disposed in an upper position of the crucible to reflect heat energy emitted from the melt in the crucible, and the composite heat insulation structure is disposed on a side of the heat shield close to the crucible and/or the composite heat insulation structure is disposed on a side of the crucible close to the monocrystalline silicon grown.

20. A monocrystalline silicon growth furnace, wherein the monocrystalline silicon growth furnace comprises a furnace body, a crucible, a heater unit, a heat shield, and a composite heat insulation structure of claim 13; the composite heat insulation structure is disposed on the heat shield;
a cavity is provided in the furnace body;
the crucible is disposed in the cavity and used for containing melt for growth of monocrystalline silicon;
the heater unit is disposed between the crucible and the furnace body to provide a heat field required for the growth of the monocrystalline silicon; and
the heat shield is disposed in an upper position of the crucible to reflect heat energy emitted from the melt in the crucible, and the composite heat insulation structure is disposed on a side of the heat shield close to the crucible and/or the composite heat insulation structure is disposed on a side of the crucible close to the monocrystalline silicon grown.
